(19) United States
(12) Patent Application Publication
(10) Pub. No.: US 2026/0133262 A1
(43) Pub. Date: May 14, 2026

(54) METHOD FOR MANAGING TRANSFORMER CORE

(71) Applicant: SHANDONG UNIVERSITY, Jinan (CN)

(72) Inventors: Tianguang LU, Jinan (CN); Qinzheng WU, Jinan (CN); Duxi ZHANG, Ningbo (CN); Qian AI, Jinan (CN); Zhaohao DING, Jinan (CN); Xing HE, Jinan (CN); Yu GUO, Jinan (CN); Donghai CHEN, Ningbo (CN)

(21) Appl. No.: 19/380,605

(22) Filed: Nov. 5, 2025

(30) Foreign Application Priority Data
Nov. 8, 2024 (CN) 2024115855646

(51) Int. Cl. G01R 31/62; G01R 1/44; G06N 3/0442

(52) U.S. Cl. CPC G01R 31/62; G01R 1/44; G06N 3/0442

(57) ABSTRACT

Provided is a method for managing a transformer core may include preliminarily obtaining a Steinmetz equation considering temperature correction factor through fitting; converting a non-sinusoidal excitation current waveform into an equivalent sinusoidal excitation current waveform for calculation, and continuing to correct the Steinmetz equation considering temperature correction factor to obtain a corrected empirical formula; and utilizing a pre-trained neural network model to process the empirical predicted value of the loss of the core and corresponding temperature, excitation current, magnetic flux density, and frequency of the excitation current to obtain a final predicted value of loss of a core to be detected. When the final predicted value of the loss exceeds a first threshold, maintenance is performed on the core to be detected; and when it exceeds a second threshold, the core to be detected is replaced.

### CROSS-REFERENCE TO RELATED APPLICATIONS

The present invention claims the priority of Chinese Patent Application No. 202411585564.6 filed with the China National Intellectual Property Administration on Nov. 8, 2024, and entitled “METHOD AND SYSTEM FOR PREDICTING TRANSFORMER CORE LOSS BASED ON EMPIRICAL FORMULA AND MODEL”, the entire content of which is incorporated by reference in the present invention to constitute a part of the present invention for all purposes.

### TECHNICAL FIELD

The present invention belongs to the technical field of transformer core management and maintenance, and particularly relates to a method for managing a transformer core.

### BACKGROUND

The statements in this section merely provide background art information related to the present invention and do not necessarily constitute the prior art.

A transformer core is an indispensable component in power conversion, and a high efficiency and high power density core design has become one of the current hot research fields. However, requirements for the high efficiency and high power density have led to an issue of high loss in magnetic components.

For general copper conductor loss, a relatively accurate loss result can be obtained through finite element simulation software. However, for certain special magnetic materials such as ferrite and nanocrystalline, due to their complex microstructure, types of loss comprise hysteresis loss, eddy current loss, and stray loss, each of which is related to numerous factors, making it difficult to accurately analyze the loss through simulation analysis, and mechanism modeling is also challenging. Traditional methods estimate the loss using empirical formulas, such as a Steinmetz equation and its various correction forms, including correction models such as Modified Steinmetz Equation (MSE), Generalized Steinmetz Equation (GSE), Improved Generalized Steinmetz Equation (iGSE), and improved-improved Generalized Steinmetz Equation (i²GSE) models. However, such methods are difficult to balance a scope of applicability, solution accuracy, and practical performance. For example, the Steinmetz equation does not consider influence of an operating temperature on the transformer core loss, its accuracy is poor, and it only considers a sinusoidal excitation wave. When the equation is corrected to consider other waveforms, the solution accuracy of the equation further decreases. A loss separation method calculates separately according to types of the core loss, which can achieve relatively accurate solutions. However, this process requires many parameters, the solution accuracy is greatly affected by a frequency, and its practicality is low.

In summary, currently, in the field of transformer core loss prediction, there are common technical problems that the transformer core loss prediction cannot be applied to different operating conditions, and the accuracy of transformer core loss prediction results is poor. This leads to a failure to promptly detect or determine the transformer core loss and its loss degree, which seriously affects a design and service life of the transformer.

### SUMMARY

To solve the above technical problems, the present invention provides a method for managing a transformer core, which utilizes a method for predicting loss based on an empirical formula and model, which can not only accurately predict the core loss but also expand an application scope as much as possible to make it applicable to different working conditions. It provides a basis for subsequent management and maintenance of the transformer core, and this method also has strong interpretability.

To achieve the above objectives, the present invention adopts the following technical solutions:

A first aspect of the present invention provides a method for managing a transformer core.

In one or more embodiments, provided is a method for managing a transformer core, comprising:
considering influence of a temperature on core loss, treating a proportional coefficient in a Steinmetz equation as a function of the temperature and characterizing the proportional coefficient using a specified exponential function, treating power exponents of both an excitation current frequency and a magnetic flux density amplitude in the Steinmetz equation as functions of the temperature, and characterizing both the power exponents using specified polynomial functions, and preliminarily obtaining a Steinmetz equation considering temperature correction factor through fitting;
considering influence of different excitation waveforms on the core loss, by introducing an equivalent sinusoidal frequency and a calculation formula thereof, converting a non-sinusoidal excitation current waveform into an equivalent sinusoidal excitation current waveform for calculation, and continuing to correct the Steinmetz equation considering temperature correction factor to obtain a corrected empirical formula;
obtaining a temperature, an excitation current, a magnetic flux density, and a frequency of the excitation current of a core to be detected, which are substituted into the corrected empirical formula to obtain an empirical predicted value of the loss of the core to be detected; and
utilizing a pre-trained improved neural network model to process the empirical predicted value of the core loss and corresponding temperature, excitation current, magnetic flux density, and frequency of the excitation current to obtain a final predicted value of the loss of the core to be detected;
when the final predicted value of the loss exceeds a first threshold, performing maintenance on the core to be detected; and,
when the final predicted value of the loss exceeds a second threshold, replacing the core to be detected.

As one embodiment, the exponential function of the proportional coefficient in the Steinmetz equation is characterized by an e-exponential.

As one embodiment, the power exponents of both the frequency of the excitation current and the amplitude of the magnetic flux density are characterized by quadratic polynomial functions.

As one embodiment, a characterization formula for the equivalent sinusoidal frequency and the corrected empirical formula are respectively as follows:

$${f}_{sin \cdot eq} = \frac{2}{Δ {B}^{2} \cdot {π}^{2}} {\int }_{0}^{{T}_{1}} {( \frac{d B}{dt} )}^{2} dt ; \\ P = f \cdot ( {k}^{′} \cdot {f}_{sin \cdot eq}^{{α}_{2} - 1} \cdot {B}_{m}^{{β}_{2}} ) = {k}_{1} {e}^{{k}_{2} \cdot T} \cdot f \cdot ( {f}_{sin \cdot eq}^{( {k}_{3} + {k}_{4} T + {k}_{5} {T}^{2} )} \cdot {B}_{m}^{( {k}_{6} + {k}_{7} T + {k}_{8} {T}^{2} )} ) ;$$

wherein, f_{sin.eg} is the equivalent sinusoidal frequency of the excitation current; ΔB is a peak-to-peak value of the magnetic flux density within one cycle, i.e., a difference between a maximum value and a minimum value;

$$\frac{d B}{dt}$$

is a rate or change or the magnetic flux density over time; T₁ is a period of the excitation waveform; k′, α₂, β₂, k₁˜k₈ are equation coefficients; f is an actual frequency of the excitation current; P is transformer core loss; T represents the temperature; and Bₘ is the magnetic flux density amplitude.

As one embodiment, the neural network model adopts a long short-term memory-multi-head attention (LSTM-AM) model.

A second aspect of the present invention provides a system for predicting transformer core loss based on an empirical formula and model.

In one or more embodiments, provided is a system for predicting transformer core loss based on an empirical formula and model, comprising:
a preliminary correction module, which is configured to consider influence of a temperature on core loss, treat a proportional coefficient in a Steinmetz equation as a function of the temperature and characterize the proportional coefficient using a specified exponential function, treat power exponents of both an excitation current frequency and a magnetic flux density amplitude in the Steinmetz equation as functions of the temperature, and characterize both the power exponents using specified polynomial functions, and preliminarily obtain a Steinmetz equation considering temperature correction factor through fitting;
an empirical formula determination module, which is configured to consider influence of different excitation waveforms on the core loss, by introducing an equivalent sinusoidal frequency and a calculation formula thereof, convert a non-sinusoidal excitation current waveform into an equivalent sinusoidal excitation current waveform for calculation, and continue to correct the Steinmetz equation considering temperature correction factor to obtain a corrected empirical formula;
an empirical predicted value calculation module, which is configured to utilize the corrected empirical formula to obtain an empirical predicted value of the core loss based on the temperature, the excitation current, the magnetic flux density, and the frequency of the excitation current; and
a core loss prediction module, which is configured to utilize a pre-trained neural network model to process the empirical predicted value of the core loss and corresponding temperature, excitation current, magnetic flux density, and frequency of the excitation current to obtain a final predicted value of the core loss.

As one embodiment, in the preliminary correction module, the exponential function of the proportional coefficient in the Steinmetz equation is characterized by an e-exponential.

As one embodiment, in the preliminary correction module, the power exponents of both the frequency of the excitation current and the amplitude of the magnetic flux density are characterized by quadratic polynomial functions.

As one embodiment, in the empirical formula determination module, a characterization formula for the equivalent sinusoidal frequency and the corrected empirical formula are respectively as follows:

$${f}_{sin \cdot eq} = \frac{2}{Δ {B}^{2} \cdot {π}^{2}} {\int }_{0}^{{T}_{1}} {( \frac{d B}{dt} )}^{2} dt ; \\ P = f \cdot ( {k}^{′} \cdot {f}_{sin \cdot eq}^{{α}_{2} - 1} \cdot {B}_{m}^{{β}_{2}} ) = {k}_{1} {e}^{{k}_{2} \cdot T} \cdot f \cdot ( {f}_{sin \cdot eq}^{( {k}_{3} + {k}_{4} T + {k}_{5} {T}^{2} )} \cdot {B}_{m}^{( {k}_{6} + {k}_{7} T + {k}_{8} {T}^{2} )} ) ;$$

wherein, f_{sin.eg} is the equivalent sinusoidal frequency of the excitation current; ΔB is a peak-to-peak value of the magnetic flux density within one cycle, i.e., a difference between a maximum value and a minimum value;

$$\frac{d B}{dt}$$

is a rate of change of the magnetic flux density over time; T₁ is a period of the excitation waveform; k′, α₂, β₂, k₁˜k₈ are equation coefficients; f is an actual frequency of the excitation current; P is transformer core loss; T represents the temperature; and Bₘ is the magnetic flux density amplitude.

As one embodiment, in the core loss prediction module, the neural network model adopts an LSTM-AM model.

Compared with the prior art, the beneficial effects of the present invention are as follows:

(1) The present invention improves a traditional Steinmetz formula by adding a temperature correction coefficient, enabling more accurate prediction of the core loss under different temperatures. Meanwhile, by introducing the calculation method of the equivalent sinusoidal frequency, the improved empirical formula can be applied to core loss calculation under various excitation waveforms.

(2) The present invention combines the improved empirical formula with an artificial intelligence model, and sequentially adopts the temperature correction factor, the equivalent sinusoidal frequency, and a black-box model to achieve hybrid-driven modeling and data, which expands the application scope of the transformer core loss prediction and improves the prediction accuracy.

(3) The artificial intelligence model of the present invention is implemented using the LSTM-AM model, which utilizes the LSTM network to capture variation patterns of physical quantities such as the magnetic flux density over time and their hidden relationships with the core loss, and utilizes the AM network to determine weights between each input feature and the output predicted value, thereby greatly improving the prediction accuracy of the transformer core loss.

### BRIEF DESCRIPTION OF THE DRAWINGS

Drawings attached to the description that constitute a part of the present invention are used to provide further understanding of the present invention. Schematic embodiments of the present invention and descriptions thereof are used to interpret the present invention and are free of constituting improper limitations to the present invention.

FIG. 1 is a schematic flow diagram of a method for predicting transformer core loss based on an empirical formula and model according to an example of the present invention;

FIG. 2 is a detailed flowchart of transformer core loss prediction based on the empirical formula and model according to an example of the present invention;

FIG. 3 is a structural schematic diagram of a system for predicting transformer core loss based on an empirical formula and model according to an example of the present invention;

FIG. 4 is a schematic diagram of an electronic device according to an example of the present invention;

FIG. 5 is a comparison of a prediction error in a polynomial form and a prediction error in an exponential form according to an example of the present invention;

FIG. 6 is a comparison of prediction loss in the exponential form and measured loss according to an example of the present invention;

FIG. 7 is an absolute error of the core loss prediction according to an example of the present invention;

FIG. 8 is a prediction error of an improved empirical formula according to an example of the present invention;

FIG. 9 is a structural diagram of an LSTM according to an example of the present invention;

FIG. 10 is an absolute error of model prediction according to an example of the present invention.

### DETAILED DESCRIPTION

The present invention will be further illustrated below in conjunction with the accompanying drawings and embodiments.

It should be pointed out that the following detailed descriptions are all exemplary and are intended to provide further illustration of the present invention. Unless otherwise indicated, all technical and scientific terms used in this specification have the same meaning as commonly understood by those skilled in the art to which the present invention belongs.

It should be noted that the terms used herein are solely for describing specific implementations and are not intended to limit exemplary implementations of the present invention. As used herein, unless otherwise indicated by context, a singular form is intended to also include a plural form. Additionally, it should be understood that when the term “include/including” and/or “comprise/comprising” is used in this specification, it indicates the presence of features, steps, operations, devices, assemblies, and/or their combinations.

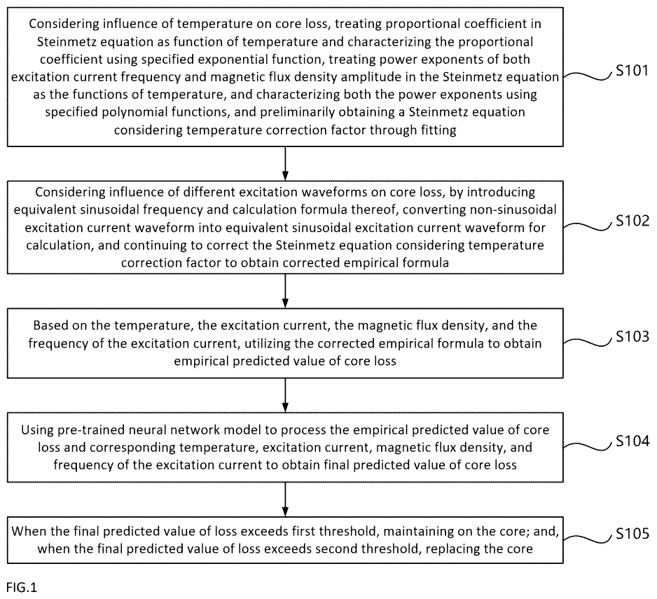

FIG. 1 is a schematic flow diagram of a method for predicting transformer core loss based on an empirical formula and model according to an example of the present invention. As shown in FIG. 1, the method for predicting transformer core loss based on an empirical formula and model in the present example may comprise:
S101, considering influence of a temperature on core loss, treating a proportional coefficient in a Steinmetz equation as a function of the temperature and characterizing the proportional coefficient using a specified exponential function, treating power exponents of both an excitation current frequency and a magnetic flux density amplitude in the Steinmetz equation as functions of the temperature, and characterizing both the power exponents using specified polynomial functions, and preliminarily obtaining a Steinmetz equation considering temperature correction factor through fitting;
S102, considering influence of different excitation waveforms on the core loss, by introducing an equivalent sinusoidal frequency and a calculation formula thereof, converting a non-sinusoidal excitation current waveform into an equivalent sinusoidal excitation current waveform for calculation, and continuing to correct the Steinmetz equation considering temperature correction factor to obtain a corrected empirical formula;
S103, obtaining a temperature, an excitation current, a magnetic flux density, and a frequency of the excitation current of a core to be detected, which are substituted into the corrected empirical formula to obtain an empirical predicted value of the loss of the core to be detected; and
S104, utilizing a pre-trained neural network model to process the empirical predicted value of the core loss and corresponding temperature, excitation current, magnetic flux density, and frequency of the excitation current to obtain a final predicted value of the loss of the core to be detected; and
S105, when the final predicted value of the loss exceeds a first threshold, performing maintenance the core to be detected; or when the final predicted value of the loss exceeds a second threshold, replacing the core to be detected.

The present example improves a traditional Steinmetz formula by adding a temperature correction coefficient, enabling more accurate prediction of the core loss under different temperatures. Meanwhile, by introducing the calculation method of the equivalent sinusoidal frequency, the improved empirical formula can be applied to core loss calculation under various excitation waveforms. It combines the improved empirical formula with a neural network model, and sequentially adopts the temperature correction factor, the equivalent sinusoidal frequency, and the artificial intelligence model to achieve hybrid-driven modeling and data, which expands the application scope of the power transformer core loss prediction and improves the prediction accuracy.

In step S101, a general form of the Steinmetz equation is as shown in formula (1).

$$P = k \cdot {f}^{α} \cdot {B}_{m}^{β} \qquad ( 1 )$$

In the above equation, P is the core loss, f is an actual frequency of the excitation current, Bₘ is the magnetic flux density amplitude, and k, α, β are coefficients that need to be fitted with data, of which values vary with a material and temperature. A value range of α is generally 1-3, and a value range of β is generally 2-3.

Although the Steinmetz equation is very classic, it is only applicable to cases where the excitation waveform is a sinusoidal wave and does not take into account influence of different temperatures. Therefore, it is very difficult to accurately predict the loss of the transformer core.

To consider the influence of temperature T based on the Steinmetz equation, the coefficient k of the equation is first considered as a function of temperature, i.e., k(T). Generally, there are two classic forms for fitting data using a function: one is a polynomial form, and the other is an exponential form. As shown in formula (2) and formula (3), these are referred to as method 1 and method 2, respectively, wherein

$$k ( T ) = {k}_{1} + {k}_{2} \cdot T + {k}_{3} \cdot {T}^{2} \qquad ( 2 )$$

$$k ( T ) = {k}_{1} {e}^{{k}_{2} T} \qquad ( 3 )$$

wherein, T denotes the temperature; k(T) is the proportional coefficient; and k₁ and k₂ are coefficients that need to be fitted.

By substituting the two forms of k(T) into formula (1) respectively, the fitting function becomes:

$$P = k ( T ) \cdot {f}^{α} \cdot {B}_{m}^{β} .$$

Nonlinear least squares fitting can be performed using a nlinfit function in Matlab to determine the coefficients of the fitting function. It can be expressed by formula (4):

$$y = f ( x , β ) + ε \qquad ( 4 )$$

wherein, y is a dependent variable, x is an independent variable, f(x,β) is a nonlinear function dependent on a parameter, and f(x,β) is a random error.

The nlinfit function estimates the parameter β by minimizing a sum of squared residuals. A specific formula is shown in formula (5).

$$\hat{β} = arg {lim}_{β} {\sum }_{i = 1}^{n} {( {y}_{i} - f ( {x}_{i} , β ) )}^{2} \qquad ( 5 )$$

wherein, \hat{β} represents an estimated value of parameter β, yᵢ represents an actual observed value, and f(xᵢ,β) represents an observed value of the model.

In the present example, the exponential function of the proportional coefficient in the Steinmetz equation is characterized by an e-exponential.

The power exponents of both the frequency of the excitation current and the amplitude of the magnetic flux density are characterized by quadratic polynomial functions.

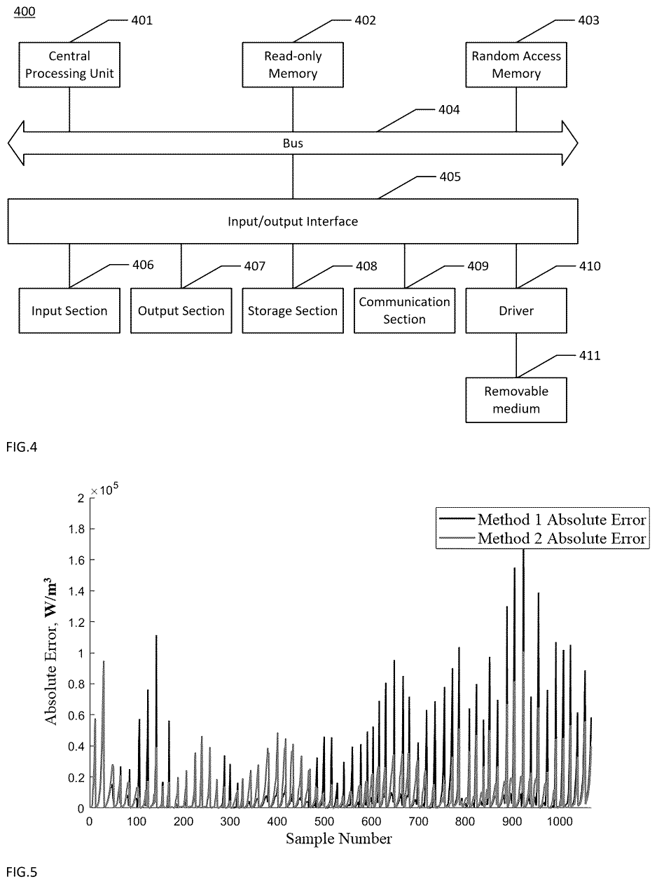

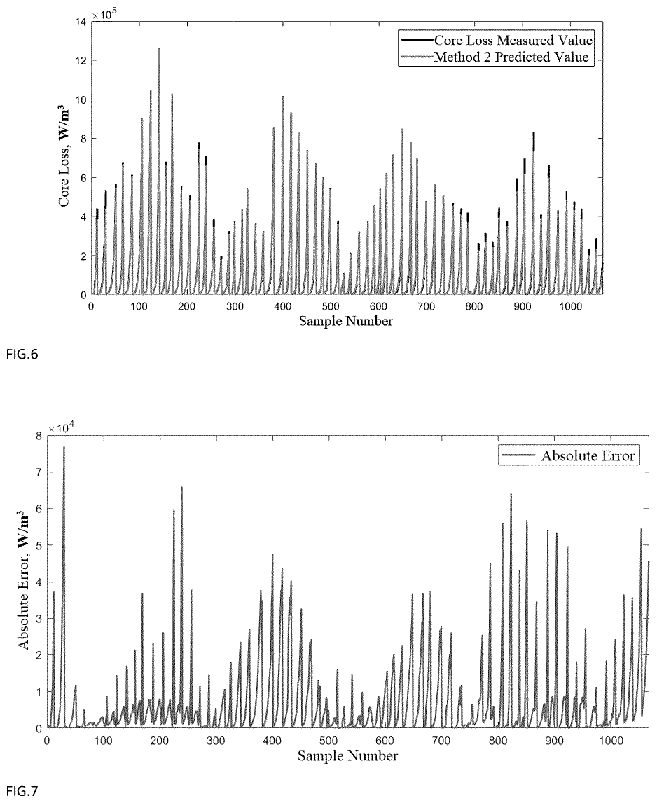

Loss experimental data of a certain material is used for the calculation of relevant fitting coefficients, wherein an experimental temperature ranges from 25° C. to 90° C., the frequency ranges from 50 Hz to 500,000 Hz, the excitation waveforms are mainly divided into a sinusoidal wave, a triangle wave, and a square wave, and the duration is one cycle. Next, the method 1 and the method 2 are respectively utilized to fit loss generated under the sinusoidal wave. An absolute error of loss prediction is shown in FIG. 5, the predicted value of the method 2 and the measured value are shown in FIG. 6, and the values of the fitting coefficients for both methods (rounded to four significant digits) are shown in Table 1 and Table 2.

TABLE 1
Coefficient values for Method 1

| Coefficient | k₁ | k₂ | k₃ | k₄ | k₅ |
|---|---|---|---|---|---|
| Value | 1.7168 | −0.0213 | 0.0001 | 1.4667 | 2.4509 |

TABLE 2
Coefficient values for Method 2

| Coefficient | k₁ | k₂ | k₃ | k₄ |
|---|---|---|---|---|
| Value | 1.4689 | −0.0082 | 1.4620 | 2.4200 |

It can be seen that the fitting error of the method 2 is smaller and the effect is significantly better than the method 1. Therefore, the method 2 is preferred for the fitting. Considering that under different temperature conditions, exponents of the frequency and magnetic flux density in the Steinmetz equation are different; the exponents of the frequency and magnetic flux density can therefore be regarded as functions of temperature. Assuming that this function can be expanded into a Taylor series, the exponents of the frequency and magnetic flux density can be further changed to polynomials related to the temperature.

The improved fitting formula is shown in formula (6).

$$P = {k}_{1} {e}^{{k}_{2} \cdot T} {f}^{( {k}_{3} + {k}_{4} \cdot T + {k}_{5} \cdot {T}^{2} )} {B}_{m}^{( {k}_{6} + {k}_{7} \cdot T + {k}_{8} \cdot {T}^{2} )} \qquad ( 6 )$$

After fitting with the formula (6), the absolute error of loss prediction under the sinusoidal wave excitation is further reduced, with a maximum absolute error not exceeding 0.8×10⁵. The absolute error is shown in FIG. 7, and the fitting coefficients of empirical formula (6) are shown in Table 3.

TABLE 3
Coefficient values for empirical formula (6)

| Coefficient | k₁ | k₂ | k₃ | k₄ | k₅ | k₆ | k₇ | k₈ |
|---|---|---|---|---|---|---|---|---|
| Value | 14.9985 | −0.0551 | 1.2228 | 0.0048 | 0.0000 | 2.1344 | 0.0058 | 0.0000 |

It can be seen from the above table that the quadratic coefficients of temperature k₅ and k₈ are basically equal to 0, which verifies the rationality of utilizing quadratic polynomials for the fitting.

In step S102, to solve the core losses under a non-sinusoidal wave excitation, the formula (6) is further improved. Some scholars have proposed an improved empirical formula for loss prediction, which is a modified Steinmetz equation, for different waveforms. This formula assumes that the core loss is related to the rate of change of the magnetic flux density. By weighting the rate of change of the magnetic flux density at different time points, a weighted average rate of change of the magnetic flux density is obtained, and it is considered that the core loss is determined by this weighted average rate of change. By this method, an equivalent sinusoidal wave frequency corresponding to any excitation waveform can be calculated. Specific expression formulas are shown in formulas (7) and (8).

A characterization formula for the equivalent sinusoidal frequency and a corrected empirical formula are respectively as follows:

$${f}_{sin \cdot eq} = \frac{2}{Δ {B}^{2} \cdot {π}^{2}} {\int }_{0}^{{T}_{1}} {( \frac{d B}{dt} )}^{2} dt \qquad ( 7 )$$

$$P = f \cdot ( {k}^{′} \cdot {f}_{sin \cdot eq}^{{α}_{2} - 1} \cdot {B}_{m}^{{β}_{2}} ) \qquad ( 8 )$$

$$P = {k}_{1} {e}^{{k}_{2} \cdot T} {f}_{sin \cdot eq}^{( {k}_{3} + {k}_{4} T + {k}_{5} {T}^{2} )} \cdot {B}_{m}^{( {k}_{6} + {k}_{7} T + {k}_{8} {T}^{2} )} \qquad ( 9 )$$

wherein, f_{sin.eg} is the equivalent sinusoidal frequency of the excitation current; ΔB is a peak-to-peak value of the magnetic flux density within one cycle, i.e., a difference between a maximum value and a minimum value;

$$\frac{d B}{dt}$$

is a rate of change of the magnetic flux density over time; T₁ is a period of the excitation waveform; k′, α₂, β₂, k₁˜k₈ are equation coefficients; f is an actual frequency of the excitation current; P is transformer core loss; T represents the temperature; and Bₘ is the magnetic flux density amplitude.

The formula (7) introduces the equivalent sinusoidal frequency, which allows calculation of the core loss under any waveform and greatly expands the applicability scope of the empirical formula. Since it is difficult to accurately obtain an analytical expression of the excitation waveform in many cases and generally only discrete sampling points are available,

$$\frac{d B}{dt}$$

in the formula (7) can be calculated by difference, and an integral term can be calculated by a trapezoidal formula, as shown in formula (10),

$${\int }_{0}^{{T}_{1}} {( \frac{d B}{dt} )}^{2} dt \approx {\sum }_{n = 1}^{N} \frac{{T}_{1}}{2 \cdot N} [ {( \frac{{B}_{n + 1} - {B}_{n}}{{T}_{1} / N} )}^{2} + {( \frac{{B}_{n} - {B}_{n - 1}}{{T}_{1} / N} )}^{2} ] \qquad ( 10 )$$

wherein, N is a total number of sampling points of the magnetic flux density within one cycle.

A combination of the formulas (7), (9), and (10) constitutes a final form of the improved empirical formula. During the fitting, the equivalent sinusoidal frequency of the excitation waveform is first calculated using the formula (10) and the formula (7), and then fitting coefficients in the formula (9) are calculated using the nlinfit function in the Matlab.

The accuracy of the improved empirical formula is tested using 3400 sample data points containing waveforms such as sinusoidal waves, triangular waves, and trapezoidal waves, and a mean squared error (MSE) thereof is calculated. A calculation formula for the MSE is shown in formula (11).

$$MSE = \frac{1}{N} {\sum }_{i = 1}^{N} {( {y}_{i} - {\hat{y}}_{i} )}^{2} \qquad ( 11 )$$

wherein, yᵢ and ŷᵢ are a true value and a predicted value of the data, respectively. An absolute error calculated according to the improved empirical formula is shown in FIG. 8, wherein MSE=8.512×10⁸.

By comparing FIG. 7 and FIG. 6, it can be seen that the absolute error increases significantly, that is, after expanding the applicability scope of the empirical formula, it is difficult to ensure the accuracy of loss calculation.

Considering that the core loss prediction effect for the non-sinusoidal excitation wave using the formulas (7), (9), and (10) is relatively poor, a black-box model constructed by an artificial intelligence method is used to further reduce the prediction error.

In the present example, the artificial intelligence model adopts an LSTM-AM model.

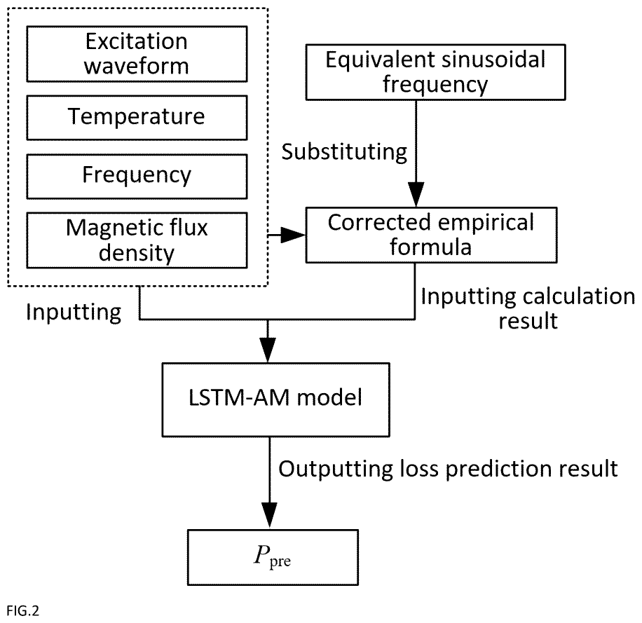

As shown in FIG. 2, a specific method is as follows: the temperature, the excitation waveform (different waveforms are distinguished by numbers 1, 2, and 3), the magnetic flux density, the frequency, and the predicted value of the loss from the improved empirical formula are used as inputs to the neural network, and an output is a final predicted value of the core loss. To accurately capture a variation law of the magnetic flux density over time and a hidden relationship with the core loss, an LSTM model is introduced, and an attention mechanism (AM) is further utilized to accurately learn a relationship between each feature and the output.

An LSTM network adds a cell state c based on a convolutional neural network (CNN) to store a long-term state, solving a problem of gradient vanishing and explosion that easily occurs during CNN training.

Assuming an input sequence X=[x₁, x₂, x₃, . . . , x_{T}], a recursive hidden layer sequentially calculates activation values of an input gate, a forget gate, an output gate, and a memory cell according to time t=1,2,3, . . . , T. Calculation formulas at time t are shown in formulas (12)-(15).

The input gate is as follows:

$${i}_{t} = σ ( {W}_{ix} {x}_{t} + {W}_{ih} {h}_{t - 1} + {W}_{ic} {c}_{t - 1} + {b}_{i} ) \qquad ( 12 )$$

wherein, σ is a Sigmoid activation function, Wᵢₓ is a weight matrix between the input gate and the input vector, Wᵢₕ is a weight matrix between the input gate and an intermediate state vector at previous time, W_{ic} is a weight matrix between the input gate and a previous memory cell cₜ₋₁ at previous time, and bᵢ is a bias vector.

The forget gate is as follows:

$${f}_{t} = σ ( {W}_{fx} {x}_{t} + {W}_{fh} {h}_{t - 1} + {W}_{fc} {c}_{t - 1} + {b}_{f} ) \qquad ( 13 )$$

wherein, W_{fx}, W_{fh}, and W_{fc} are weight matrices between the forget gate and xₜ, hₜ₋₁, and cₜ₋₁, respectively; and b_{f} is a bias vector of the forget gate.

The memory cell is as follows:

$${c}_{t} = {f}_{t} {c}_{t - 1} + {i}_{t} ϕ ( {W}_{ch} {h}_{t - 1} + {W}_{cx} {x}_{t} + {b}_{c} ) \qquad ( 14 )$$

wherein, W_{cx} and W_{ch} are weight matrices between the memory cell and xₜ and hₜ₋₁, respectively; φ is a hyperbolic tangent function; and b_{c} is a bias vector.

The output gate is as follows:

$${o}_{t} = σ ( {W}_{ox} {x}_{t} + {W}_{oh} {h}_{t - 1} + {W}_{oc} {c}_{t - 1} + {b}_{o} ) \qquad ( 15 )$$

wherein, Wₒₓ, Wₒₕ, and W_{oc} are weight matrices between the output gate and xₜ, hₜ₋₁, and cₜ₋₁, respectively.

The hidden layer output is as follows:

$${h}_{t} = {o}_{t} ϕ ( {c}_{t} ) \qquad ( 16 )$$

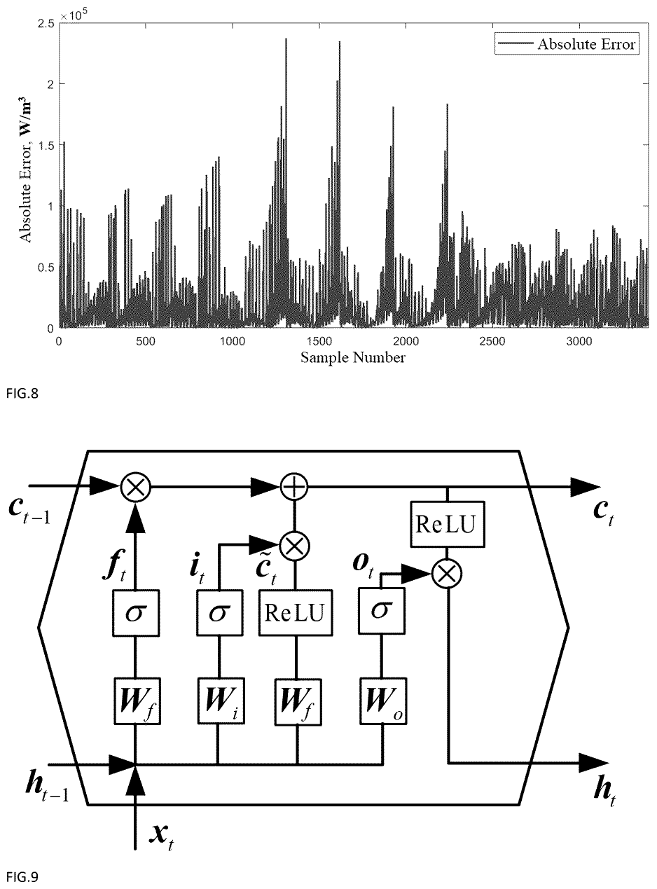

The activation function utilized in the present example is a rectified linear unit (ReLU). A structural diagram of the LSTM model is shown in FIG. 9.

The essence of the attention mechanism is weighted summation. Assuming there are k feature vectors hᵢ(i=1,2,3, . . . , k) of d dimensions, information of these k feature vectors is integrated, and the integrated vector is denoted as h*. Here, a weighted average is taken, as shown in formula (17).

$${h}^{*} = {\sum }_{i = 1}^{k} {a}_{i} {h}_{i} \qquad ( 17 )$$

wherein, aᵢ is a weight, and a fundamental purpose of the AM is to obtain a reasonable weight.

The calculation for the weight consists of two steps:

(1) A scoring function g is designed; for each hᵢ, a corresponding score sᵢ is calculated, wherein scoring is based on a correlation between hᵢ and an object of interest; and the greater the correlation, the greater the value of sᵢ.

(2) The obtained k scores are processed by a Softmax function to obtain the final weight aᵢ, wherein a specific formula is shown in formula (18).

$${a}_{i} = soft max ( {s}_{i} ) \qquad ( 18 )$$

The AM adopted in the present example is constructed by adding a fully connected layer with the same number of nodes as the number of units in an LSTM layer between the LSTM layer and a fully connected layer with 1 neuron, as shown in formula (19).

$$a = σ ( {W}_{a} {h}_{t} + {b}_{a} ) \qquad ( 19 )$$

wherein, hₜ is an output vector of the LSTM layer at the current time, Wₐ is an attention weight matrix, and bₐ is an attention bias vector.

An output of each neuron in the LSTM layer has different importance to the current network output. The output of the LSTM can be regarded as basic encoding of an input sequence. The AM in the network is responsible for automatically learning the attention weights, capturing global features, and measuring the importance of each output of the LSTM layer to the overall network output. That is, the outputs of the LSTM layer and the network output are used as inputs to the AM, thereby learning a function of the weight coefficients with respect to both, and the learned weights can further reflect their correlation.

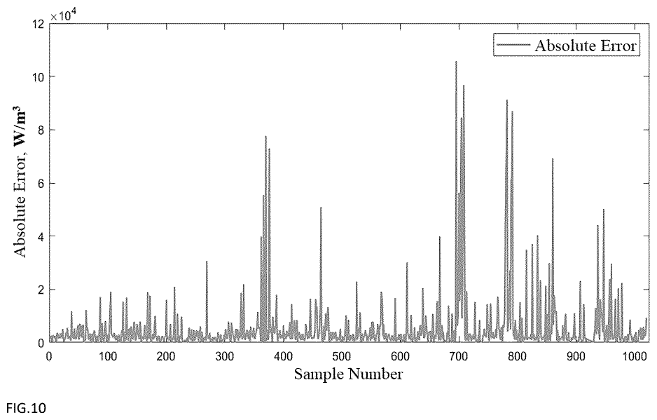

The 3,400 sets of core loss sample data are randomly divided into a 70% training set and a 30% test set. For the 30% test set, the absolute error of core loss prediction is shown in FIG. 10. The mean squared error MSE=1.441×10⁸. Compared with utilizing only the improved empirical formula, the MSE index decreased by 83.39%, showing a significant effect.

In the present example, for those skilled in the art, it is possible to establish core loss degree levels and corresponding treatment measures for all the levels according to historical experience in judging the core loss degree. By setting several thresholds, the obtained final predicted value of the loss of the core to be detected is compared with the thresholds, and corresponding treatment measures are taken for the core to eliminate its loss.

### Specifically:

when the final predicted value of the loss is greater than a first threshold, maintenance of the core to be detected is performed; and
when the final predicted value of the loss is greater than a second threshold, the core to be detected is replaced.

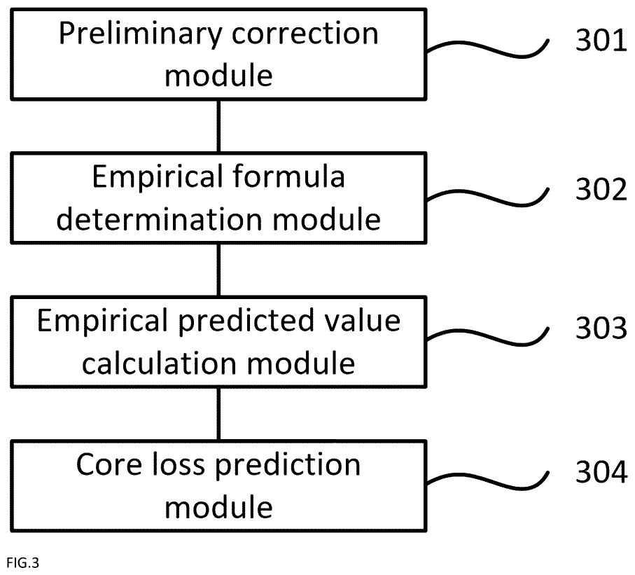

FIG. 3 is a structural schematic diagram of a system for predicting transformer core loss based on an empirical formula and model according to an example of the present invention. The present example corresponds to the method for predicting transformer core loss based on an empirical formula and model shown in FIG. 1. As shown in FIG. 3, the system for predicting transformer core loss based on an empirical formula and model in the present example may comprise:
a preliminary correction module 301, which is configured to consider influence of a temperature on core loss, treat a proportional coefficient in a Steinmetz equation as a function of the temperature and characterize the proportional coefficient using a specified exponential function, treat power exponents of both an excitation current frequency and a magnetic flux density amplitude in the Steinmetz equation as functions of the temperature, and characterize both the power exponents using specified polynomial functions, and preliminarily obtain a Steinmetz equation considering temperature correction factor through fitting;
an empirical formula determination module 302, which is configured to consider influence of different excitation waveforms on the core loss, by introducing an equivalent sinusoidal frequency and a calculation formula thereof, convert a non-sinusoidal excitation current waveform into an equivalent sinusoidal excitation current waveform for calculation, and continue to correct the Steinmetz equation considering temperature correction factor to obtain a corrected empirical formula;
an empirical predicted value calculation module 303, which is configured to utilize the corrected empirical formula to obtain an empirical predicted value of the core loss based on the temperature, the excitation current, the magnetic flux density, and the frequency of the excitation current; and
a core loss prediction module 304, which is configured to utilize a pre-trained neural network model to process the empirical predicted value of the core loss and corresponding temperature, excitation current, magnetic flux density, and frequency of the excitation current to obtain a final predicted value of the core loss.

In the specific implementation process, in the preliminary correction module 301, the exponential function of the proportional coefficient in the Steinmetz equation is characterized by an e-exponential.

In the preliminary correction module 301, the power exponents of both the frequency of the excitation current and the amplitude of the magnetic flux density are characterized by quadratic polynomial functions.

In the empirical formula determination module 302, a characterization formula for the equivalent sinusoidal frequency and the corrected empirical formula are respectively as follows:

$${f}_{sin . eq} = \frac{2}{Δ {B}^{2} \cdot {π}^{2}} {\int }_{0}^{{T}_{1}} {( \frac{dB}{dt} )}^{2} dt ;$$

$$P = f \cdot ( {k}^{′} \cdot {f}_{sin . eq}^{{α}_{2} - 1} \cdot {B}_{m}^{{β}_{2}} ) = {k}_{1} {e}^{{k}_{2} \cdot T} \cdot f \cdot ( {f}_{sin . eq}^{( {k}_{3} + {k}_{4} T + {k}_{5} {T}^{2} )} \cdot {f}_{m}^{( {k}_{6} + {k}_{7} T + {k}_{8} {T}^{2} )} ) ;$$

wherein, f_{sin.eq} is the equivalent sinusoidal frequency of the excitation current; ΔB is a peak-to-peak value of the magnetic flux density within one cycle, i.e., a difference between a maximum value and a minimum value;

$$\frac{dB}{dt}$$

is a rate of change of the magnetic flux density over time; T₁ is a period of the excitation waveform; k′, α₂, β₂, k₁˜k₈ are equation coefficients; f is an actual frequency of the excitation current; P is transformer core loss; T represents the temperature; and Bₘ is the magnetic flux density amplitude.

In the core loss prediction module 304, the neural network model adopts an LSTM-AM model.

It should be noted that each module in the system for predicting transformer core loss based on an empirical formula and model shown in FIG. 3 corresponds one-to-one with each step in the method for predicting transformer core loss based on an empirical formula and model shown in FIG. 1, and a specific implementation process is the same and will not be repeated herein.

Referring to FIG. 4, a schematic diagram of an electronic device is provided. It should be noted that the electronic device 400 shown in FIG. 4 is merely an example and should not impose any limitation on the functions and scope of use of the embodiments of the present invention.

As shown in FIG. 4, the electronic device 400 comprises a central processing unit (CPU) 401, which can execute various appropriate actions and processes according to a program stored in a read-only memory (ROM) 402 or a program loaded from a storage section 408 into a random access memory (RAM) 403. Various programs and data required for system operations are also stored in the RAM 403. The central processing unit 401, the ROM 402, and the RAM 403 are connected to each other via a bus 404. An input/output (I/O) interface 405 is also connected to the bus 404.

The following components are connected to the I/O interface 405: an input section 406 including a keyboard, mouse, etc.; an output section 407 including devices such as a cathode ray tube (CRT), a liquid crystal display (LCD), and a speaker; a storage section 408 including a hard disk; and a communication section 409 including network interface cards such as a local area network (LAN) card and a modem. The communication section 409 performs communication processing via a network such as the Internet. A driver 410 is also connected to the I/O interface 405 as needed. A removable medium 411, such as a magnetic disk, an optical disk, a magneto-optical disk, a semiconductor memory, is installed on the driver 410 as required, so that a computer program read therefrom can be installed into the storage section 408 as needed.

When the central processing unit 401 of the electronic device according to the present example executes the program, it implements the steps of the method for predicting transformer core loss based on an empirical formula and model as shown in FIG. 1.

Specifically, according to the embodiments of the present application, the process described above with reference to the flowchart may be implemented as a computer software program. For example, the embodiments of the present application comprises a computer program product comprising a computer program carried on a computer-readable medium, the computer program including program codes for performing the method shown in FIG. 1. In such embodiments, the computer program may be downloaded and installed from a network via the communication section 409 and/or installed from the removable medium 411. When the computer program is executed by the central processing unit 401, various functions defined in the apparatus of the present application are performed.

The computer program instructions corresponding to the method shown in FIG. 1 may also be stored in a computer-readable memory that guides the computer or another programmable data processing device to operate in a specific manner, so that the instructions stored in the computer-readable memory generate a manufactured product including an instruction device, and the instruction device implements the functions specified in one or more flows in the flow diagram and/or one or more blocks in the block diagram.

It will be understood by a person skilled in the art that the implementation of all or part of the processes of the methods of the embodiments described above can be accomplished by instructing a relevant hardware by a computer program, which may be stored on a computer readable storage medium, and which, when being executed, may include the processes of the embodiments of the methods described above. The storage medium may be a disk, optical disc, Read-Only Memory (ROM) or Random Access Memory (RAM) etc.

The foregoing is merely illustrative of the preferred embodiments of the present invention and is not intended to be limiting of the present invention, and for those skilled in the art, the present invention may have various changes and modifications. Any modifications, equivalent substitutions, improvements, and the like within the spirit and principles of the invention are intended to be included within the scope of the present invention.

1. A method for predicting transformer core loss based on an empirical formula and model, comprising:
considering influence of a temperature on core loss, treating a proportional coefficient in a Steinmetz equation as a function of the temperature and characterizing the proportional coefficient using a specified exponential function, treating power exponents of both an excitation current frequency and a magnetic flux density amplitude in the Steinmetz equation as functions of the temperature, and characterizing both the power exponents using specified polynomial functions, and preliminarily obtaining a Steinmetz equation considering temperature correction factor through fitting;
considering influence of different excitation waveforms on the core loss, by introducing an equivalent sinusoidal frequency and a calculation formula thereof, converting a non-sinusoidal excitation current waveform into an equivalent sinusoidal excitation current waveform for calculation, and continuing to correct the Steinmetz equation considering temperature correction factor to obtain a corrected empirical formula;
a characterization formula for the equivalent sinusoidal frequency and the corrected empirical formula are respectively as follows:
$${f}_{sin . eq} = \frac{2}{Δ {B}^{2} \cdot {π}^{2}} {\int }_{0}^{{T}_{1}} {( \frac{dB}{dt} )}^{2} dt ;$$
$$P = f \cdot ( {k}^{′} \cdot {f}_{sin . eq}^{{α}_{2} - 1} \cdot {B}_{m}^{{β}_{2}} ) = {k}_{1} {e}^{{k}_{2} \cdot T} \cdot f \cdot ( {f}_{sin . eq}^{( {k}_{3} + {k}_{4} T + {k}_{5} {T}^{2} )} \cdot {f}_{m}^{( {k}_{6} + {k}_{7} T + {k}_{8} {T}^{2} )} ) ;$$
wherein, f_{sin.eg} is the equivalent sinusoidal frequency of the excitation current; ΔB is a peak-to-peak value of the magnetic flux density within one cycle, i.e., a difference between a maximum value and a minimum value;
$$\frac{dB}{dt}$$
is a rate of change of the magnetic flux density over time; T₁ is a period of the excitation waveform; k′, α₂, β₂, k₁˜k₈ are equation coefficients; f is an actual frequency of the excitation current; P is transformer core loss; T represents the temperature;
and Bₘ is the magnetic flux density amplitude;
based on the temperature, the excitation current, the magnetic flux density, and the frequency of the excitation current, utilizing the corrected empirical formula to obtain an empirical predicted value of the core loss; and
utilizing a pre-trained neural network model to process the empirical predicted value of the core loss and corresponding temperature, excitation current, magnetic flux density, and frequency of the excitation current to obtain a final predicted value of the core loss.

2. The method for predicting transformer core loss based on an empirical formula and model according to claim 1, wherein the exponential function of the proportional coefficient in the Steinmetz equation is characterized by an e-exponential.

3. The method for predicting transformer core loss based on an empirical formula and model according to claim 1, wherein the power exponents of both the frequency of the excitation current and the amplitude of the magnetic flux density are characterized by quadratic polynomial functions.

4. The method for predicting transformer core loss based on an empirical formula and model according to claim 1, wherein the neural network model adopts an LSTM-AM model.

5. A system for predicting transformer core loss based on an empirical formula and model, comprising:
a preliminary correction module, which is configured to consider influence of a temperature on core loss, treat a proportional coefficient in a Steinmetz equation as a function of the temperature and characterize the proportional coefficient using a specified exponential function, treat power exponents of both an excitation current frequency and a magnetic flux density amplitude in the Steinmetz equation as functions of the temperature, and characterize both the power exponents using specified polynomial functions, and preliminarily obtain a Steinmetz equation considering temperature correction factor through fitting;
an empirical formula determination module, which is configured to consider influence of different excitation waveforms on the core loss, by introducing an equivalent sinusoidal frequency and a calculation formula thereof, convert a non-sinusoidal excitation current waveform into an equivalent sinusoidal excitation current waveform for calculation, and continue to correct the Steinmetz equation considering temperature correction factor to obtain a corrected empirical formula;
a characterization formula for the equivalent sinusoidal frequency and the corrected empirical formula are respectively as follows:
$${f}_{sin . eq} = \frac{2}{Δ {B}^{2} \cdot {π}^{2}} {\int }_{0}^{{T}_{1}} {( \frac{dB}{dt} )}^{2} dt ;$$
$$P = f \cdot ( {k}^{′} \cdot {f}_{sin . eq}^{{α}_{2} - 1} \cdot {B}_{m}^{{β}_{2}} ) = {k}_{1} {e}^{{k}_{2} \cdot T} \cdot f \cdot ( {f}_{sin . eq}^{( {k}_{3} + {k}_{4} T + {k}_{5} {T}^{2} )} \cdot {f}_{m}^{( {k}_{6} + {k}_{7} T + {k}_{8} {T}^{2} )} ) ;$$
wherein, f_{sin.eg} is the equivalent sinusoidal frequency of the excitation current; ΔB is a peak-to-peak value of the magnetic flux density within one cycle, i.e., a difference between a maximum value and a minimum value;
$$\frac{dB}{dt}$$
is a rate of change or the magnetic flux density over time; T₁ is a period of the excitation waveform; k′, α₂, β₂, k₁˜k₈ are equation coefficients; f is an actual frequency of the excitation current; P is transformer core loss; T represents the temperature;
and Bₘ is the magnetic flux density amplitude;
an empirical predicted value calculation module, which is configured to utilize the corrected empirical formula to obtain an empirical predicted value of the core loss based on the temperature, the excitation current, the magnetic flux density, and the frequency of the excitation current; and
a core loss prediction module, which is configured to utilize a pre-trained neural network model to process the empirical predicted value of the core loss and corresponding temperature, excitation current, magnetic flux density, and frequency of the excitation current to obtain a final predicted value of the core loss.

6. The system for predicting transformer core loss based on an empirical formula and model according to claim 5, wherein in the preliminary correction module, the exponential function of the proportional coefficient in the Steinmetz equation is characterized by an e-exponential.

7. The system for predicting transformer core loss based on an empirical formula and model according to claim 5, wherein in the preliminary correction module, the power exponents of both the frequency of the excitation current and the amplitude of the magnetic flux density are characterized by quadratic polynomial functions.

8. The system for predicting transformer core loss based on an empirical formula and model according to claim 5, wherein in the core loss prediction module, the neural network model adopts a long short-term memory-multi-head attention (LSTM-AM) model.
